(19) United States
(12) Patent Application Publication
(10) Pub. No.: US 2006/0017148 A1
(43) Pub. Date: Jan. 26, 2006

(54) Semiconductor package and method for its manufacture

(76) Inventor: Min-Ho Lee, Chungcheongnam-do (KR)

Correspondence Address: MARGER JOHNSON & MCCOLLOM, P.C., 210 SW MORRISON STREET, SUITE 400, PORTLAND, OR, 97204, US

(21) Appl. No.: 11/154,075

(22) Filed: Jun. 15, 2005

(30) Foreign Application Priority Data
Jul. 22, 2004 (KR) 2004-57112

(51) Int. Cl. H01L 23/02

(52) U.S. Cl. 257/686

(57) ABSTRACT

A method of manufacturing a semiconductor package having a double encapsulant structure. The method comprises preparing a group substrate. The group substrate includes a plurality of semiconductor chips arranged on the top surface, which chips typically are stacked. The semiconductor chips are electrically connected with the group substrate by bonding wires. A first liquid molding compound covers the top surface of the group substrate to form a first encapsulant. A second liquid molding compound covers the first encapsulant to form a second encapsulant. The group substrate may be divided into individual semiconductor packages. The second encapsulant—which includes a smaller percentage by weight of filler than does the first encapsulant—typically covers an incomplete molding portion of the first encapsulant. Accordingly, the invention reduces the overall thickness of the encapsulant and ensures complete molding.

### CROSS REFERENCE TO RELATED APPLICATIONS

This U.S. non-provisional application claims priority under 35 U.S.C. § 119 of Korean Patent Application No. 2004-57112, filed on Jul. 22, 2004, the entire contents of which are incorporated herein by reference.

### BACKGROUND OF THE INVENTION

1. Field of the Invention

The invention relates to a semiconductor package and, more particularly, to a semiconductor package having a double encapsulant structure.

2. Description of the Related Art

A semiconductor package manufacturing process may include a molding process. The molding process may seal a semiconductor chip and an electrical connection of the semiconductor chip and a substrate using a liquid molding compound.

Lately, the electronic industry has been seeking to manufacture electronic products that are extremely small, light weight, operate at high speeds, have multiple functions and have high performance, all at an effective cost. One of the methods used to try to attain such a goal is a package assembly technique. Thanks to this technique, new types of packages have been developed, for example, a chip scale or chip size package (CSP) and a stack chip package.

The CSP has a number of advantages over a typical plastic package. Of all the advantages, the most important is the package size. According to international semiconductor associations, such as the Joint Electron Device Engineering Council (JEDEC), and Electronic Industry Association of Japan (EIAJ), the CSP is defined as a package whose size is not larger than 1.2 times the size of the chip.

The CSP has been mainly employed in electronic products requiring miniaturization and mobility, such as digital camcorders, portable telephones, notebooks, and memory cards. CSPs include semiconductor devices such as digital signal processors (DSP), application-specific integrated circuits (ASIC), and micro-controllers. CSPs also include memory devices such as dynamic random access memories (DRAM) and flash memories. Use of CSPs having memory devices is steadily increasing. Over fifty varieties of CSPs are being developed or produced all over the world.

The stack chip package is one example of a multi-chip package. The stack chip package has at least two semiconductor chips stacked on a substrate.

A group molding process is used to simultaneously manufacture a plurality of semiconductor packages in a single substrate. The substrate is then divided into individual semiconductor packages.

During the molding process, a molding compound often flows at a different speed on a semiconductor chip mounting area than on a peripheral area, thereby causing incomplete molding. This is primarily due to the differential depths of these areas, since the semiconductor chip mounting area extends above the peripheral area by the height of the semiconductor chip(s).

FIG. 1 is a cross-sectional view of a conventional chip stack semiconductor package. FIG. 2 is a plan view illustrating a flow of a molding compound during a group molding process in the manufacture of the chip stack semiconductor package of FIG. 1. FIG. 3 is a plan view of the chip stack semiconductor package of FIG. 1 after the group molding process.

Referring to FIG. 1, the chip stack semiconductor package 10 includes a substrate 11 having substrate pads 13, and semiconductor chips 17 and 19 stacked on the substrate 11. The lower semiconductor chip 17 is hereinafter referred to as a first chip and the upper semiconductor chip 19 is hereinafter referred to as a second chip. A first bonding wire 23 electrically connects the first chip 17 and the substrate pad 13. A second bonding wire 25 electrically connects the second chip 19 and the substrate pad 13. A spacer 21 typically is interposed between the first and second chips 17 and 19. The spacer 21 prevents an electrical short that otherwise might occur due to the contact of the first bonding wire 23 and the second chip 19. An encapsulant 27 seals the first and second chips 17 and 19, the first and second bonding wires 23 and 25 and the connection, and the encapsulant 27 also protects them from the external environment. Ball pads 15 are formed on the bottom surface of the substrate 11. Solder balls 29, in turn, may be, formed on the ball pads 15.

Referring to FIGS. 2 and 3, the encapsulant 27 can be formed using a liquid molding compound 27a by a group molding method. A plurality of semiconductor packages can be simultaneously manufactured on a substrate 12. The substrate 12 can include a plurality of the individual semiconductor package substrates (11 of FIG. 1). The substrate 12 is hereinafter referred to as a group substrate.

The group substrate 12 then is divided into individual semiconductor packages after molding and solder ball forming processes.

When the thickness of the semiconductor chips 17 and 19 occupy a considerable portion of the entire thickness (h1) of the encapsulant 27, incomplete molding can occur on the upper surface of the second chip 19. Specifically, the liquid molding compound 27a can flow (B1) at a different speed at the upper surface of the second chip 19 than at its peripheral area 14. Stated another way, the liquid molding compound 27a can flow at a higher speed at the peripheral area 14 than at the upper surface of the second chip 19. The speed difference often leads to incomplete molding on the upper surface of the second chip 19. So-called weld lines 24 might form due to the incomplete molding. Weld lines 24 are undesirable, since they can adversely impact the performance of the affected semiconductor chip 19.

Some chip stack semiconductor packages 10 use a molding compound containing filler material characterized by low hygroscopicity. Low hygroscopicity of the filler material reduces fluidity or flowability of the molding compound, thereby causing incomplete molding, for example, in the form of weld lines 24. The result, especially in the case of packages having relatively large-sized semiconductor chips, is low yield or performance reliability.

In order to ensure complete molding and thus reliably high yield and performance, the encapsulant 27 should extend a predetermined height (h2) above the upper surface of the second chip 19. This ensures flow of the molding compound (27a) more evenly along the upper surface of the second chip 19. However, increased height leads to an increase in the overall thickness (h1) of the encapsulant 27. Height (h2) will be understood to be determined in part by flow resistance, which in turn is dependent upon the surface areas of first and second chips 17, 19.

For example, if the size of semiconductor chips 17 and 19 is 6 mm in width and 13 mm in length (producing surface areas of approximately 78 mm²), then to ensure even flow the thickness (h2) of the encapsulant 27 above the upper surface of the second chip 19 should be at least 220 μm. Therefore, the entire thickness (h1) of the encapsulant 27 can be approximately 650 μm or more, based upon the stacking geometries and prior art encapsulation and packaging techniques.

### SUMMARY OF THE INVENTION

An exemplary embodiment of the invention involves a method of manufacturing a chip stack semiconductor package having a double encapsulant structure that features a reduced height above the uppermost semiconductor chip and yet ensures complete molding.

The invented method of manufacturing a chip stack semiconductor package having a double encapsulant structure comprises preparing a group substrate. The group substrate includes a plurality of semiconductor chips arranged on the top surface. The semiconductor chips are selectively electrically connected with the group substrate by bonding wires. A first liquid molding compound covers the top surface of the group substrate to form a first encapsulant. A second liquid molding compound covers the first encapsulant to form a second encapsulant. The group substrate is divided into individual semiconductor packages.

In accordance with exemplary embodiments of the invention, the second encapsulant covers, and thereby corrects or repairs, any incomplete molding caused by poor or uneven flow of the first encapsulant.

In accordance with exemplary embodiments of the invention, at least two semiconductor chips per individual package are stacked on the top surface of the group substrate.

In accordance with exemplary embodiments of the invention, the second molding compound contains a smaller percentage by weight (wt %) of filler and thus is more fluid or flowable (i.e. the fluid is less viscous or resistant to flow) than is the first molding compound containing a larger percentage by weight (wt %) of filler. For example, the first molding compound might typically have a filler content from at least approximately 80 wt %-94 wt %, whereas the second molding compound might typically have a filler content from at most approximately 45 wt %-85 wt %.

In accordance with exemplary embodiments of the invention, the thickness of the second encapsulant typically might be between 20 μm and 50 μm. This is surprisingly far less than the 220 μm of conventional second encapsulant thicknesses.

In accordance with exemplary embodiments of the invention, the group substrate may be selected from a group consisting of a tape wiring substrate, a ceramic substrate and a lead frame.

### BRIEF DESCRIPTION OF THE DRAWINGS

These and other features and advantages of the exemplary embodiments of the invention will be readily understood with reference to the following detailed description thereof provided in conjunction with the accompanying drawings, wherein like reference numerals designate like structural elements.

FIG. 1 is a cross-sectional view of a conventional chip stack semiconductor package.

FIG. 2 is a plan view illustrating flow of a molding compound during a group molding process in the manufacture of the chip stack semiconductor package of FIG. 1.

FIG. 3 is a plan view of the chip stack semiconductor package of FIG. 1 after the group molding process.

FIGS. 4 through 12 are views of each step of a method of manufacturing a chip stack semiconductor package having a double encapsulant structure in accordance with an exemplary embodiment of the invention.

FIG. 4 is a plan view of a group substrate after a wire-bonding process;

FIG. 5 is a cross-sectional view taken along line V-V of FIG. 4.

FIG. 6 is a plan view illustrating flow of a first molding compound during a first molding process.

FIG. 7 is a plan view of a chip stack semiconductor package having a first encapsulant.

FIG. 8 is a cross-sectional view taken along line VIII-VIII of FIG. 7;

FIG. 9 is a plan view illustrating flow of a second molding compound during a second molding process.

FIG. 10 is a cross-sectional view taken along line X-X of FIG. 9.

FIG. 11 is a plan view of the process of dividing a group substrate into individual chip stack semiconductor packages.

FIG. 12 is a cross-sectional view of a chip stack semiconductor package having a double encapsulant structure in accordance with an exemplary embodiment of the invention.

FIG. 13 is a cross-sectional view of an exposed lead frame package having a double encapsulant structure in accordance with another exemplary embodiment of the invention.

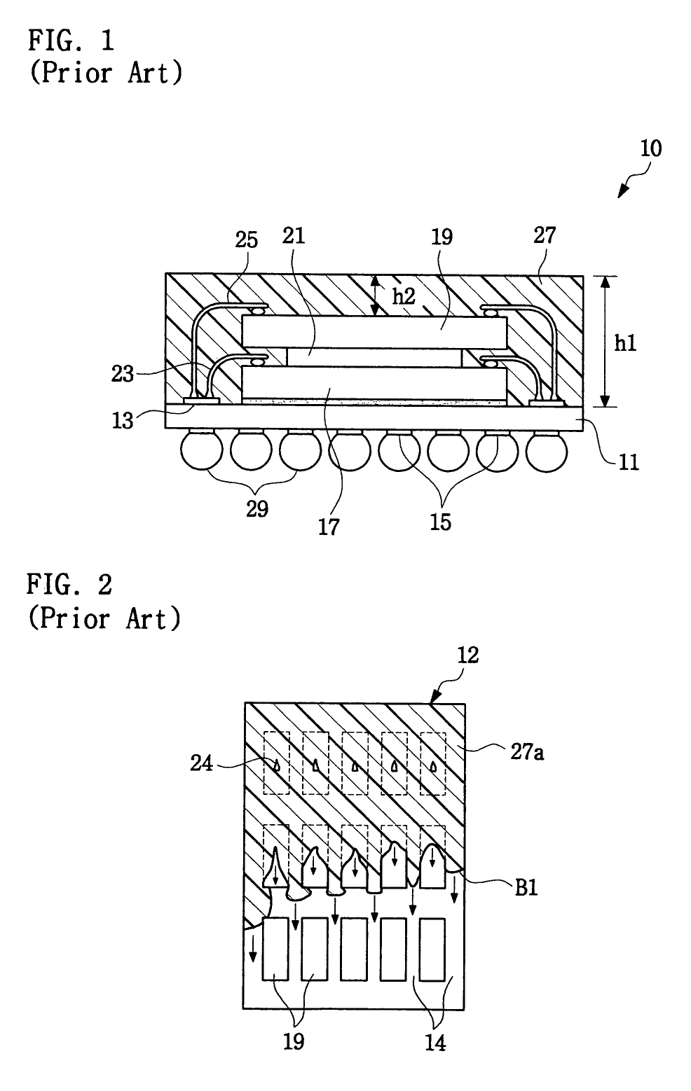

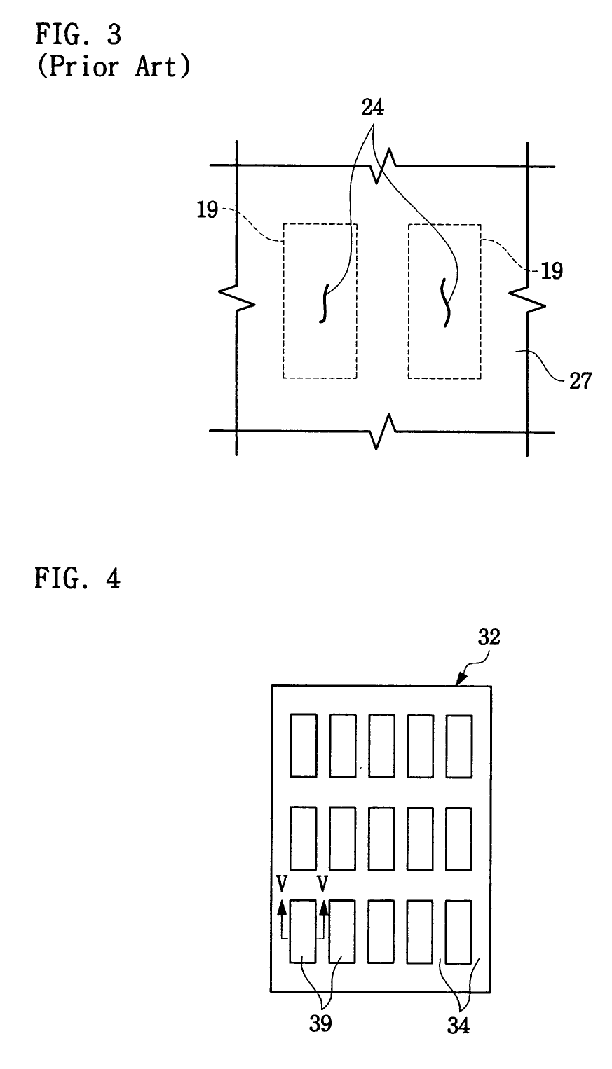

These drawings are provided for illustrative purposes only and are not drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the exemplary embodiments of the invention.

### DETAILED DESCRIPTION

The invention will now be described more fully hereinafter with reference to the accompanying drawings, in which exemplary embodiments of the invention are illustrated. This invention may, however, be embodied in many different forms and should not be construed as limited to the particular embodiments set forth herein. Rather, these embodiments are described so that this disclosure will be thorough and complete, and will fully convey the scope of the invention to those skilled in the art.

In the description, well-known structures and processes have not been described or illustrated in detail to avoid obscuring the invention. It will be appreciated that for simplicity and clarity of illustration, some elements illustrated in the figures have not necessarily been drawn to scale. For example, the dimensions of some of the elements have been exaggerated or reduced relative to other elements for clarity.

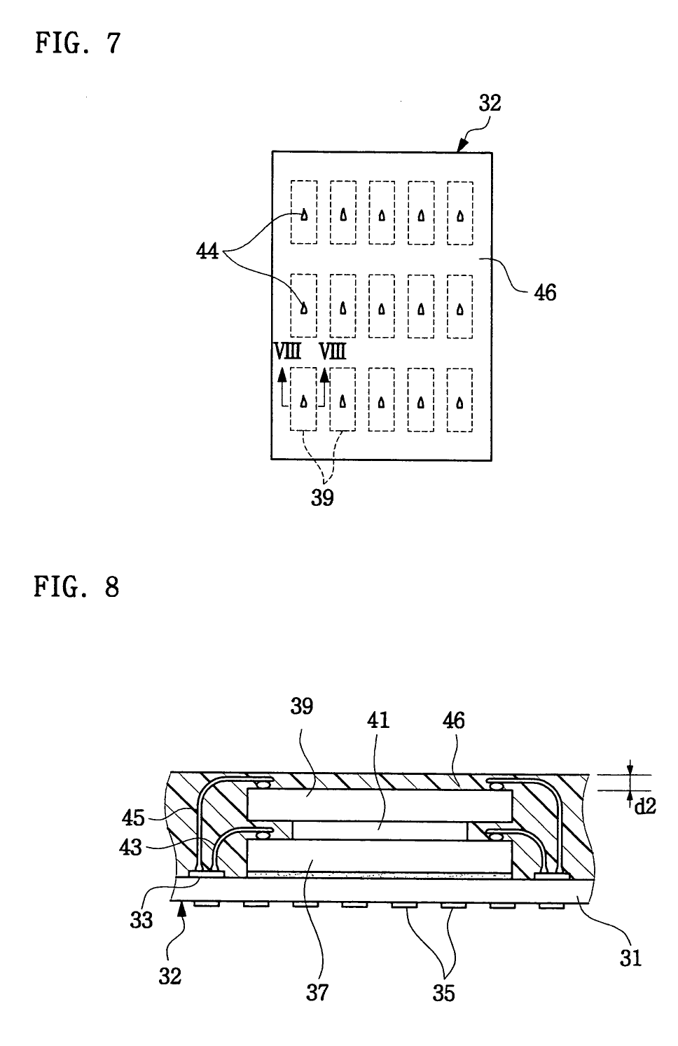

FIGS. 4 through 12 are views of each step of a method of manufacturing a chip stack semiconductor package having a double encapsulant structure in accordance with an exemplary embodiment of the invention.

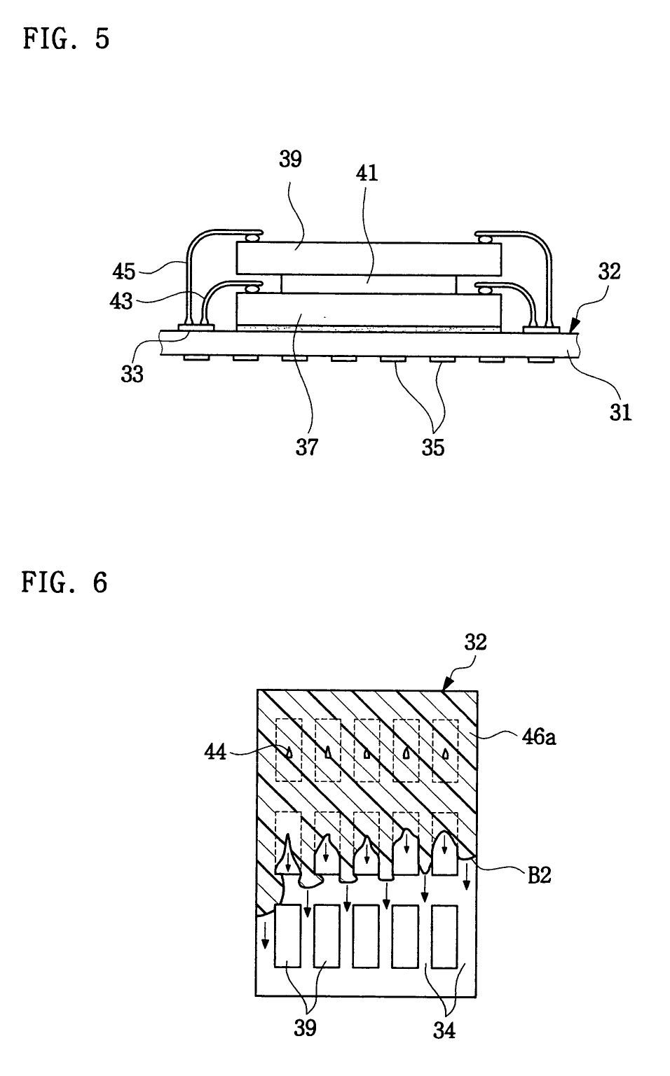

Referring to FIGS. 4 and 5, the method of manufacturing a chip stack semiconductor package having a double encapsulant structure starts with preparing a group substrate 32 including plural instances of individual substrate packages such as package 31 (to be separated later from the remaining packages, as by scoring and snapping, sawing routing or any other suitable means).

The group substrate 32 includes a first chip 37 and a second chip 39 stacked on the first chip 37. A spacer 41 typically is interposed between the first chip 37 and the second chip 39. A plurality of semiconductor chips including the first and second chips 37 and 39 are arranged on the group substrate 32, for example, in rows and columns. A first bonding wire 43 electrically connects the first chip 37 with corresponding substrate pads 33 of the group substrate 32. A second bonding wire 45 electrically connects the second chip 39 with corresponding substrate pads 33 of the group substrate 32. (Those of skill in the art will appreciate that preferably the second bonding wire 45 is captured within first encapsulant (layer) 46, as illustrated, but that within the spirit and scope of the invention it may instead by captured within second encapsulant (layer) 48. Thus, first encapsulant (layer) 46 within the spirit and scope of the invention might reach only approximately the first elevation defined by the top surfaces of the top semiconductor chips 39.) Ball pads 35 are formed on the bottom surface of the group substrate 32. Solder balls in turn are formed on the ball pads 35. Those of skill in the art will appreciate that the first and second bonding wires 43 and 45 can be formed using a bump reverse wire bonding method for a thin semiconductor package. Those of skill in the art also will appreciate that reference numeral 34 indicates a peripheral area within the array of stacked semiconductor chips and between adjacent stacked chips and along the outside edges thereof.

The group substrate 32 can include any of a tape wiring substrate, a printed circuit board, and a ceramic substrate.

Referring to FIGS. 6 through 8, a first encapsulant 46 is formed on the group substrate 32 using a first group molding method. A first liquid molding compound 46a is injected on the top surface of the group substrate 32 to cover the first and second chips 37 and 39, the spacer 41 and first and second bonding wires 43 and 45.

In accordance with a typical embodiment of the invention, the size of the first and second chips 37 and 39 is 6 mm in width and 13 mm in length. Conventionally, the thickness of an encapsulant above the upper surface of a second chip has been at least 220 μm. In accordance with this exemplary embodiment of the invention, however, the thickness (d2) of the first encapsulant 46 above the nominal first defined elevation of the upper surface of the second chip 39 is only approximately 100 μm, which represents a surprisingly substantial reduction in overall encapsulant thickness.

The first molding compound 46a is conventional. It can be, for example, an epoxy molding compound (EMC) having a filler content from at least approximately 80 wt %-94 wt %.

The first encapsulant 46 having the reduced height can undesirably produce weld lines 44 on the second chip 39. The weld lines 44 are caused by differential flow (B2) speeds of the first molding compound 46a as between the upper surface of the second chip 39 (where flow is relatively inhibited) and the peripheral area 34 (where flow is relatively free).

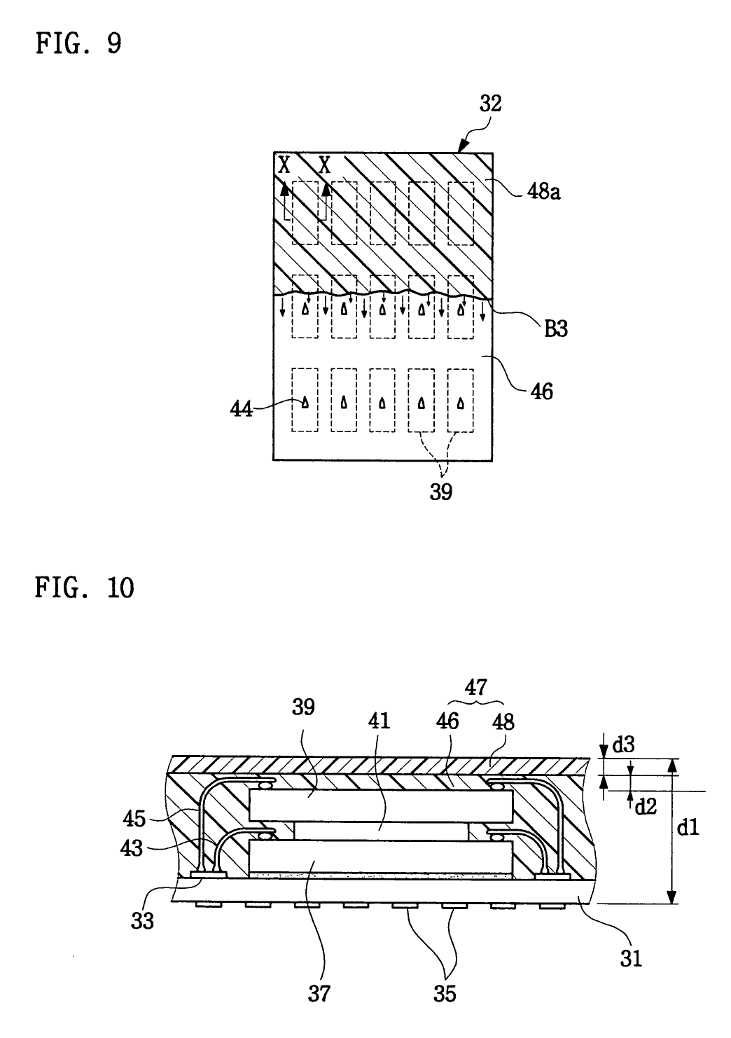

Referring to FIGS. 9 and 10, a second encapsulant 48 is formed on the first encapsulant 46 using a second group molding method. A second liquid molding compound 48a is injected or otherwise flowed over the first encapsulant 46. This is why the chip stack semiconductor package of this embodiment is referred to as a double encapsulant structure.

The first encapsulant 46 can exhibit the weld lines 44, but, as a whole, the upper surface of the first encapsulant 46 still typically is relatively flat. The second molding compound 48a flows (B3) substantially simultaneously and uniformly at the upper surface of the first encapsulant 46 over the stacked semiconductor chip area as well as over the peripheral area 34. Therefore, the second encapsulant 48 achieves a second defined elevation slightly higher than the first defined elevation and thus typically covers the weld lines 44, thereby ensuring complete molding and avoiding the incomplete molding problem that plagues prior art encapsulation and packaging methods.

The second molding compound 48a in accordance with a preferred embodiment of the invention contains a smaller percentage by weight of filler and exhibits higher fluidity, i.e. better flowability, than the first molding compound 46a. For example, an EMC is used in the second molding compound 48a that is characterized by a filler content from at most approximately 45 wt %-85 wt %.

For example, if the size of the first and second chips 37 and 39 is 6 mm in width and 13 mm in length then the thickness (d2) of the first encapsulant 46 above the upper surface of the second chip 39 is approximately 100 μm. The thickness (d3) of the second encapsulant 48 above the upper surface of the first encapsulant 46 is then between 20 μm and 50 μm. Consequently, the entire thickness (d1) of the encapsulant 47 including the first and second encapsulants 46 and 48 in accordance with the invention can be reduced by 70 μm to 100 μm, compared with the conventional semiconductor package.

The invention reduces the likelihood of warpage of the package by controlling the property of the second encapsulant 48 such as its CTE and/or its thickness.

Next, the group substrate 32 can have the solder balls (49 of FIG. 12) formed on the ball pads 35. Those of skill in the art will appreciate that the ball pads 35 permit interconnections with other circuit elements, as by the mounting of individuated substrates carrying their corresponding stacked semiconductor chips to another substrate, printed circuit board, flex circuit, etc.

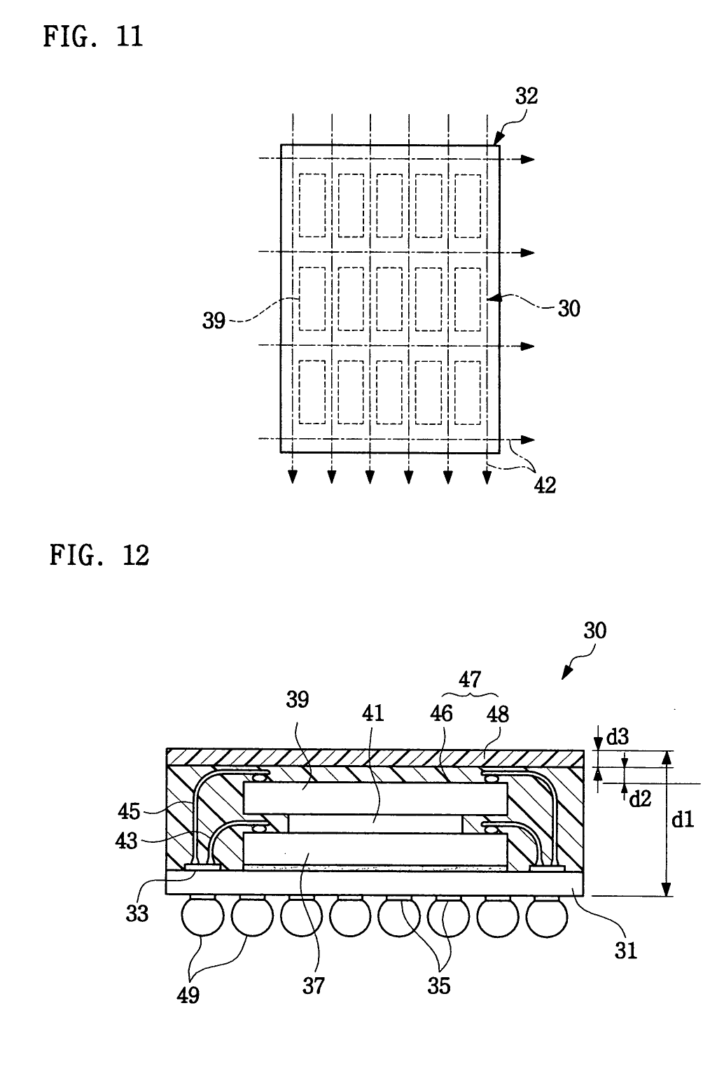

Referring to FIGS. 11 and 12, the group substrate 32 may be divided into individual semiconductor packages 30, each with its corresponding substrate 31. The group substrate 32 may be sawn or otherwise separated into individual substrates 31, i.e. it may be individuated, along scribe lines 42 by a sawing or scoring-and-snapping or routing or other suitable means (not shown).

Although this embodiment shows the chip stack semiconductor package 30 having two semiconductor chips, the invention is applicable in the alternative to a semiconductor package having a single semiconductor chip. Particularly, the invention provides advantages to semiconductor packaging in which the thickness of a semiconductor chip may occupy a considerable portion of the thickness of the semiconductor package. Thus, the entire thickness of the semiconductor package may be reduced while ensuring complete molding.

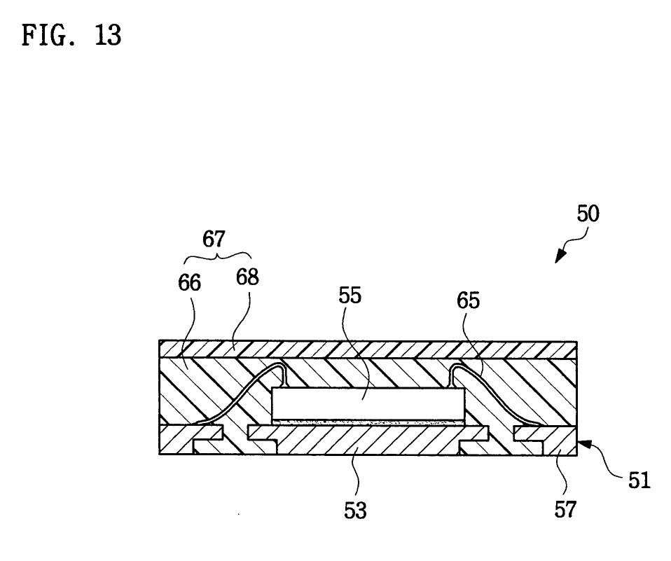

FIG. 13 is a cross-sectional view of an exposed lead frame package (ELP) having a double encapsulant structure in accordance with another exemplary embodiment of the invention.

Referring to FIG. 13, the ELP 50 typically includes a die pad 53 and a semiconductor chip 55 mounted on the die pad 53. Leads 57 are formed adjacent to the die pad 53. Bonding wires 65 selectively electrically connect the semiconductor chip 55 with corresponding leads 57. An encapsulant 67 seals the die pad 53, the semiconductor chip 55, the leads 57, and the bonding wires 65. The bottom surfaces of the die pad 53 and leads 57 may be exposed, as illustrated, whereby the exposed portion of the leads 57 are useful as external connection terminals.

The encapsulant 67 can be formed by the same method as in the previous exemplary embodiment. First, a lead frame 51 is prepared. The lead frame 51 includes the leads 57 connected to the semiconductor chip 55. A first encapsulant 66 is then formed using a first liquid molding compound by a first group molding method. The first encapsulant 66 seals the die pad 53, the semiconductor chip 55, the leads 57, and the bonding wires 65. The first encapsulant 66 typically exposes the bottom surfaces of the die pad 53 and the leads 57. A second encapsulant 68 is then formed using a second liquid molding compound by a second group molding method. The second liquid molding compound is injected or otherwise flowed over the first encapsulant 66 to cover the first encapsulant 66.

Preferably, as described above, the second encapsulant 68 is thinner and its encapsulant material has less percentage filler by weight than the first encapsulant 66, thereby increasing fluidity and improving flowability of the second encapsulant 68 over the first encapsulant 66.

Although this embodiment shows the semiconductor package 50 having the lead frame 51, the lead frame 51 may be replaced with a printed circuit board, a tape wiring substrate, or an equivalent structure.

A method of manufacturing a semiconductor package in accordance with the invention comprises forming a first encapsulant and forming a second encapsulant. The first encapsulant will be understood in effect substantially to ‘level the playing field’ whereby the peripheral areas are filled and the areas above the surfaces of the semiconductor chips are covered. The second encapsulant then will be understood to further level and even out the planar top surface of encapsulant by more smoothly flowing a thinner layer of encapsulant above the thicker first layer of encapsulant. The invention nevertheless may be understood to reduce the overall thickness of encapsulant and to reduce the likelihood of incomplete molding whereby encapsulant voids or recesses above semiconductor chips where flow is relatively inhibited (referred to herein as weld lines) are minimized or eliminated.

Although the exemplary embodiments of the invention have been described in detail hereinabove, it should be understood that many variations and/or modifications of the basic inventive concepts herein taught, which may appear to those skilled in the art, will still fall within the spirit and scope of the exemplary embodiments of the invention as defined in the appended claims. For example, the first and second encapsulants can be formed by group molding processes. However, the first and second encapsulants alternatively can be formed by conventional molding processes such as individual molding processes.

What is claimed is:

1. A method of manufacturing a semiconductor package, the method comprising:
preparing a group substrate having a top surface and a bottom surface, the group substrate having a plurality of semiconductor chips arranged on the top surface, the group substrate being selectively electrically connected with the plurality of semiconductor chips;
injecting a first liquid molding compound on the top surface of the group substrate to form a first encapsulant;
injecting a second liquid molding compound on the first encapsulant to form a second encapsulant; and
dividing the group substrate into individual semiconductor packages.

2. The method of claim 1, wherein injecting the first liquid molding compound generates an incomplete molding portion of the first encapsulant, and wherein the second encapsulant covers the incomplete molding portion.

3. The method of claim 1, wherein at least some of the plurality of semiconductor chips are stacked atop one another on the top surface of the group substrate.

4. The method of claim 1, wherein the second liquid molding compound contains a smaller percentage of filler by weight than the first liquid molding compound.

5. The method of claim 1, wherein the group substrate includes substrate pads formed on the top surface and ball pads formed on the bottom surface, the substrate pads being electrically connected with corresponding ones of the semiconductor chips, the ball pads being electrically connected with the substrate pads.

6. The method of claim 1, wherein the first liquid molding compound is characterized by a filler content of greater than approximately 80 wt %-94 wt %.

7. The method of claim 1, wherein the second liquid molding compound is characterized by a filler content of less than approximately 45 wt %-85 wt %.

8. The method of claim 1, wherein the thickness of the second encapsulant is between approximately 20 μm and 50 μm.

9. The method of claim 1, wherein the group substrate is selected from a group consisting of a tape wiring substrate, a printed circuit board, and a lead frame.

10. The method of claim 1 which further comprises:
forming ball pads on the bottom surface; and
forming solder balls on the ball pads.

11. The method of claim 1, wherein the group substrate includes a die pad having a semiconductor chip and leads arranged adjacent to the die pad, the leads being electrically connected with the semiconductor chip by bonding wires.

12. The method of claim 11, wherein the first encapsulant seals the semiconductor chip, the bonding wires, the die pad, and the leads, and wherein the first encapsulate exposes bottom surfaces of the die pad and of the leads, and wherein the exposed bottom surfaces of the leads are configured to function as external connection terminals.

13. A semiconductor package comprising:
a group substrate having a top planar surface and a bottom planar surface, the substrate including a plurality of semiconductor chips mounted on a top surface thereof, the semiconductor chips defining therebetween and therearound peripheral areas of the top surface, with plural top surfaces of the semiconductor chips defining a plane at a first defined elevation above the top planar surface of the substrate;
a first encapsulant layer extending across the top surface substantially to fill the peripheral areas at least approximately to the first defined elevation of the plane above the top planar surface of the substrate;
a second encapsulant layer extending across the top surfaces of the stacked semiconductor chips to a second defined elevation slightly above the first defined elevation that is higher than the plane defined by the plural tope surfaces of the semiconductor chips;
the first and the second encapsulant layers being formed of encapsulants containing differential percentages by weight of liquid filler material wherein the percentage by weight of liquid filler material contained in the second encapsulant layer is lower than that of the first encapsulant layer thereby to produce greater fluidity and a more planar upper surface of the second encapsulant layer.

14. The semiconductor package of claim 13, wherein the thickness of the second encapsulant layer is between approximately 20 μm and 50 μm.

15. The semiconductor package of claim 13, wherein the encapsulant forming the first encapsulant layer contains a filler content of greater than approximately 80-94 wt % and wherein the encapsulant forming the second encapsulant layer contains a filler content of less than approximately 45 wt %-85 wt %.

16. The semiconductor package of claim 13, wherein the group substrate is selected from a group consisting of a tape wiring substrate, a printed circuit board, and a leadframe.

17. The semiconductor package of claim 13, wherein the group substrate includes substrate pads formed on the top surface of the substrate and ball pads formed on the bottom surface of the substrate, the substrate pads being electrically connected with corresponding ones of the semiconductor chips, the ball pads being electrically connected with the substrate pads.

18. The semiconductor package of claim 13, wherein the ball pads have solder balls electrically connected therewith.

19. The semiconductor package of claim 13, wherein the group substrate includes a die pad having a semiconductor chip and leads arranged adjacent to the die pad and selectively electrically connected with the semiconductor chip by bonding wires.

20. The semiconductor package of claim 19, wherein the first encapsulant layer substantially seals the semiconductor chip, the bonding wires, the die pad and the leads and exposes bottom surfaces of the die pad and of the leads, and wherein the exposed surfaces of the leads are configured to function as external connection terminals.
